(19) United States
(12) Patent Application Publication
(10) Pub. No.: US 2008/0264476 A1
(43) Pub. Date: Oct. 30, 2008

(54) SOLAR CELL WITH DIAMOND LIKE CARBON COVER GLASS

(75) Inventors: Paul Sharps, Albuquerque, NM (US); Daniel Aiken, Cedar Crest, NM (US)

Correspondence Address: EMCORE CORPORATION, 1600 EUBANK BLVD, S.E., ALBUQUERQUE, NM, 87123, US

(73) Assignee: EMCORE CORPORATION, Somerset, NJ (US)

(21) Appl. No.: 11/741,387

(22) Filed: Apr. 27, 2007

(51) Int. Cl. H01L 31/00

(52) U.S. Cl. 136/255; 136/252; 136/259; 136/261

(57) ABSTRACT

A solar cell including a semiconductor body including at least one photoactive junction; and a diamond like carbon layer deposited over the top surface of the semiconductor body.

### BACKGROUND OF THE INVENTION

1. Field of the Invention

The present invention relates to the field of solar cell semiconductor devices, and particularly to the composition of the protective layer or coverglass over the semiconductor body.

2. Description of the Related Art

Photovoltaic cells, also called solar cells, are one of the most important new energy sources that have become available in the past several years. Considerable effort has gone into solar cell development. As a result, solar cells are currently being used in a number of commercial and consumer-oriented applications. While significant progress has been made in this area, the requirement for solar cells to meet the needs of more sophisticated applications has not kept pace with demand. Applications such as satellites used in data communications have dramatically increased the demand for solar cells with improved power and energy conversion characteristics.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as the payloads become more sophisticated, the design efficiency of solar cells, which act as the power conversion devices for the on-board power systems, become increasingly more important.

Solar cells are often fabricated in vertical, multifunction structures, and disposed in horizontal arrays, with the individual solar cell connected together in a series. The shape and structure of an array, as well as the number of cells it contains, are determined in part by the desired output voltage and current.

After fabrication of the solar cell, it is bonded with a ceria containing coverglass. Although such coverglass may be adequate for terrestrial applications, the use of solar cells in space presents additional challenges.

Prior to the present invention, the materials and fabrication steps disclosed in the prior art have not been described for producing a solar cell based on utilizing a diamond like carbon protective layer.

### SUMMARY OF THE INVENTION

1. Objects of the Invention

It is an object of the present invention to provide an improved coverglass for a solar cell.

It is an object of the invention to provide an improved solar cell structure for space applications.

It is still another object of the invention to provide a method of manufacturing a solar cell using a diamond like carbon protective layer.

Additional objects, advantages, and novel features of the present invention will become apparent to those skilled in the art from this disclosure, including the following detailed description as well as by practice of the invention. While the invention is described below with reference to preferred embodiments, it should be understood that the invention is not limited thereto. Those of ordinary skill in the art having access to the teachings herein will recognize additional applications, modifications and embodiments in other fields, which are within the scope of the invention as disclosed and claimed herein and with respect to which the invention could be of utility.

2. Features of the Invention

Briefly, and the general terms, the present invention provides a solar cell comprising: a semiconductor body including at least one photoactive junction; and a diamond like carbon layer deposited over the top surface of the semiconductor body.

The present invention further provides a method of manufacturing a solar cell by providing a substrate; depositing on the substrate a sequence of layers of semiconductor material forming a solar cell; and mounting a protective glass including a diamond like carbon layer over the solar cell.

### BRIEF DESCRIPTION OF THE DRAWINGS

These and other features and advantages of this invention will be better and more fully appreciated by reference to the following detailed description when considered in conjunction with the accompanying drawings, wherein:

FIG. 1 is an enlarged cross-sectional view of the solar cell as known in the prior art at the end of the process steps of forming the layers of the solar cell on a first substrate;

FIG. 2 is an enlarged cross-sectional view of the solar cell according to the present invention in a first embodiment;

FIG. 3 is a cross-sectional view of the solar cell structure according to the present invention in a second embodiment; and

FIG. 4 is a cross-sectional view of the solar cell according to the present invention in a third embodiment.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

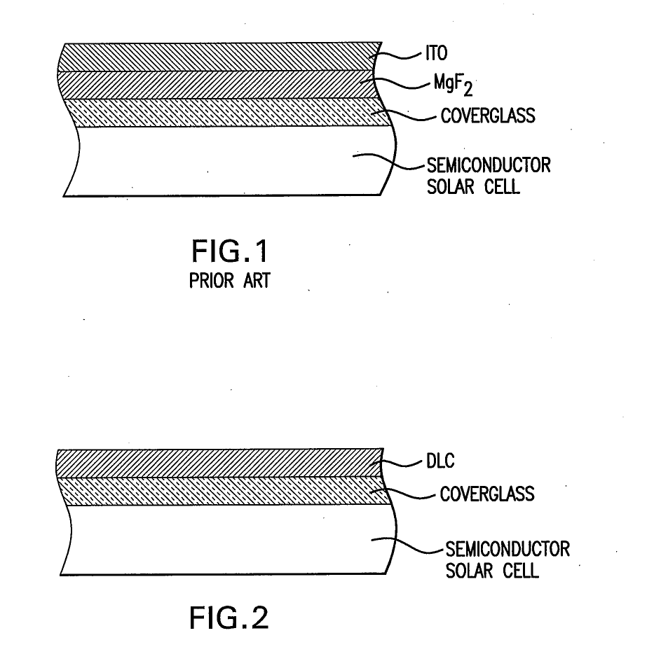

FIG. 1 depicts a cross-sectional view of a solar cell according to the prior art, and in particular to the layers forming a protective coating disposed above the semiconductor body.

The current standard practice is to use layers of MgF2 as an anti-reflective coating (ARC) and indium-tin oxide (ITO) as a conductive coating on coverglass over the semiconductor body. The ITO helps to alleviate electrostatic discharge (ESD) on solar cells with coverglass. The issue with these coatings is that they are not always robust, and can thin or erode in a space environment, particularly if they are subject to exhaust from the ion thrusters that are used to position satellites in orbit.

As shown in FIG. 2, one embodiment of the present invention is to use diamond like carbon (DLC) coatings, from 10 nm to 1000 nm in thickness, to replace MgF2 and indium tin oxide (ITO) coatings that are currently in use on space solar cell coverglass. DLC coatings are more robust and can hold up in the space environment more that MgF2 or ITO coatings, particularly near the exhaust from ion thrusters, used to position satellites in orbit. The thruster exhaust erodes the coatings on the coverglass, and hence having a tougher, more resilient coating is necessary so that the performance of the solar cells does not degrade due to coverglass degradation while in orbit. The DLC coatings act as both an ARC and can also be made to be conductive, hence alleviating ESD.

Although the preferred embodiment utilizes the III-V semiconductor materials described above, the embodiment is only illustrative, and it should be noted that the multifunction solar cell structure could be formed by any suitable combination of group III to V elements listed in the periodic table subject to lattice constant and band gap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorous (P), arsenic (As), antimony (Sb), and bismuth (Bi).

In the preferred embodiment, the substrate is gallium arsenide, the emitter layer is composed of InGa(Al)P, and the base layer is composed of InGa(Al)P. The Al term in parenthesis means that Al is also is an optional constituent, and in this instance may be used in an amount ranging from 0% to 30%.

Current high efficiency multijunction solar cells typically use dual layer TiOx/Al₂O₃ coatings on the front to act as an anti-reflection coating (ARC). TiOx has an index of refraction of about 2.3, and Al₂O₃ has an index of refraction of about 1.7. By depositing appropriate layers on the front or top surface of the GaInP₂/GaAs/Ge semiconductor body multijunction device, the Al₂O₃/TiOx structure reduces the reflection of incoming sunlight to much lower levels. While effective, the Al₂O₃/TiOx still has limitations.

Diamond like coatings (DLC) can cover a wider range of indices of refraction than the Al₂O₃ and TiOx coatings. The wider available range of the indices of refraction can lead to a more effective ARC. There are several possibilities, which really depend on the availability of DLCs with different indices of refraction. The wider range of the indices of refraction combined with the transparency of the DLCs are what make these films ideal for new ARCs. The thickness of the DLCs will have to be theoretically calculated and then experimentally verified to provide the minimal desired reflectance.

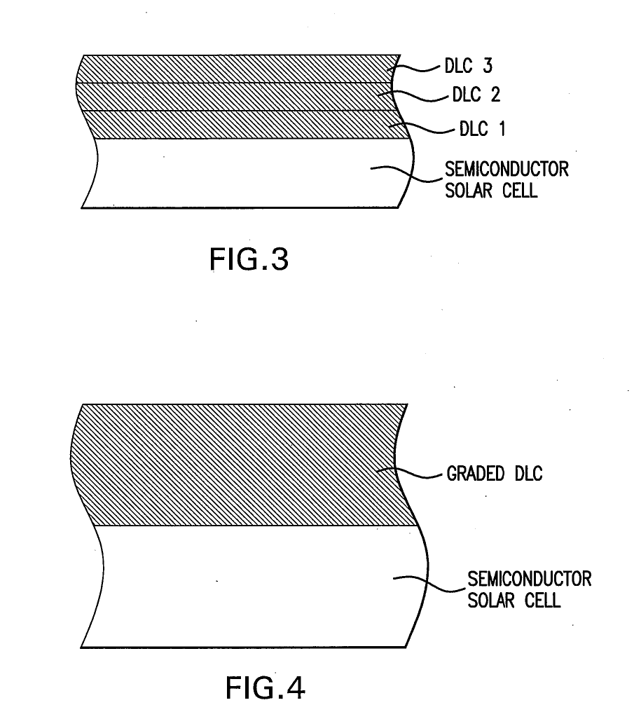

In the embodiment shown in FIG. 3, the ARC may be comprised of three DLC layers, including a low index of refraction on the topmost layer DLC³, a middle index of refraction in layer DLC², and a high index of refraction in the layer DLC¹ nearest the multifunction solar cell. Alternate embodiments may include four or more DLC layers arranged from a lower index of refraction on the topmost layer of the solar cell to additional layers with increasing indices of refraction nearer the solar cell.

In the embodiment shown in FIG. 4, the ARC may also be comprised of continually graded DLC having a low index of refraction near the top surface of the solar cell monotonically or continuously increasing to a high index of refraction present in the layers near the top of the semiconductor body. The continually graded ARC is a DLC of appropriate thickness (typically from 10 nm to 1000 nm) and index of refraction.

Although this aspect invention has been described in certain specific embodiments, many additional modifications and variations would be apparent to those skilled in the art. This aspect of the present invention is, therefore, considered in all respects to be illustrative and not restrictive. The scope of this aspect of the invention is indicated by the relevant appended claims, and all changes that come within the meaning and range of equivalents thereof are intended to be embraced therein.

It will be understood that each of the elements described above, or two or more together, also may find a useful application in other types of constructions differing from the types described above.

While the aspect of the invention has been illustrated and described as embodied in a solar power system using III-V compound semiconductors, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and therefore, such adaptations should and are intended to be comprehended within the meaning and range of equivalence of the following claims.

1. A solar cell comprising:
a semiconductor body including at least one photoactive junction; and
a diamond like carbon layer deposited over the top surface of said semiconductor body.

2. A solar cell as defined in claim 1, further comprising a coverglass deposited over the top surface of said semiconductor body, and wherein said diamond like carbon layer is deposited over said coverglass.

3. A solar cell as defined in claim 1, where said diamond like carbon layer comprises at least two sublayers of different refractive index.

4. A solar cell as defined in claim 1, where said diamond like carbon layer comprises a graded index material having a refractive index that monotonically decreases from the top surface of the semiconductor body to the top surface of the diamond like carbon layer.

5. A solar cell as defined in claim 1, where said diamond like carbon layer is between 10 nm and 1000 nm in thickness.

6. The solar cell as defined in claim 1 wherein the semiconductor body comprises group III-V elements.

7. The solar cell as defined in claim 1 wherein the semiconductor body comprises a multijunction solar cell.

8. A solar cell as defined in claim 1, wherein the semiconductor body includes a substrate selected from the group consisting of germanium or GaAs.

9. A multijunction solar cell as defined in claim 7, wherein a first solar subcell is composed of germanium.

10. A multijunction solar cell as defined in claim 9, wherein a second solar subcell is composed of GaAs.

11. A multijunction solar cell as defined in claim 10, wherein a third solar subcell is composed of GaInP₂.

12. A solar cell as defined in claim 1, where said diamond like carbon layer provides an antireflective coating.

13. A solar cell as defined in claim 2, wherein said coverglass is composed of ceria-doped glass and is adhered to the semiconductor body by a substantially transparent adhesive, said adhesive remaining substantially transparent when exposed to an AM0 space environment.
